(19) United States
(12) Patent Application Publication
(10) Pub. No.: US 2026/0221631 A1
(43) Pub. Date: Jul. 30, 2026

(54) DEVICE INCLUDING A BUS BAR FOR CURRENT MEASUREMENT

(71) Applicant: MILWAUKEE ELECTRIC TOOL CORPORATION, Brookfield, WI (US)

(72) Inventor: Jonathan D. Quenzer, German Valley, IL (US)

(21) Appl. No.: 19/453,132

(22) Filed: Jan. 20, 2026

Related U.S. Application Data
(60) Provisional application No. 63/749,040, filed on Jan. 24, 2025.

(51) Int. Cl. H01M 50/581; G01R 31/36; G01R 31/374; G01R 31/3842; H01M 10/42; H01M 10/46; H01M 10/48; H01M 50/247; H02H 7/18

(52) U.S. Cl. CPC H01M 50/581; G01R 31/3644; G01R 31/374; G01R 31/3842; H01M 10/425; H01M 10/46; H01M 10/486; H01M 50/247; H02H 7/18; H01M 2200/10; H01M 2220/30

(57) ABSTRACT

A device including a conductive path for passing electric current. The device also includes a terminal of the device and a bus bar connected in the conductive path and electrically connected to the terminal of the device. The bus bar includes a first section made of a first material, a second section made of the first material, and a third section made of a second material. The third section is at least partially positioned between the first section and the second section. The second material has a lower temperature coefficient of resistance than the first material. The devices also include a plurality of voltage taps electrically connected to the bus bar. The plurality of voltage taps is operable to measure a voltage across the third section.

### RELATED APPLICATIONS

This application claims the benefit of U.S. Provisional Patent Application No. 63/749,040, filed January 24, 2025, the entire content of which is incorporated herein by reference.

### FIELD

Embodiments described herein provide devices including a conductive path for passing electric current.

### SUMMARY

Existing devices that include current measurement capabilities can include a copper bus bar for current measurement. However, copper has a very high temperature coefficient of resistance. For example, for every 1°C, the resistance of copper can change by approximately 0.400% (4,000 parts-per-million [“ppm”]). Even with the use of a thermal model and a temperature sensor (e.g., a thermistor) near the bus bar, an estimated temperature of the bus bar can be off by 20°C or more, which results in a current measurement error of approximately 8% (20*0.400 = 8%). However, if the material that is used for current measurement has a lower temperature coefficient of resistance such that for every 1°C, the resistance of material only changes by approximately 0.010% (100 parts-per-million [“ppm”]) the current measurement error can be reduced to 0.2% (20*0.01 = 0.2%).

Devices described herein include a conductive path for passing electric current. The devices also include a terminal of the device and a bus bar connected in the conductive path and electrically connected to the terminal of the device. The bus bar includes a first section made of a first material, a second section made of the first material, and a third section made of a second material. The third section is at least partially positioned between the first section and the second section. The second material has a lower temperature coefficient of resistance than the first material. The devices also include a plurality of voltage taps electrically connected to the bus bar. The plurality of voltage taps is operable to measure a voltage across the third section.

In some aspects, the device is a battery pack and the bus bar is within the battery pack.

In some aspects, the device is a battery pack charger and the bus bar is within a battery pack charger.

In some aspects, the device is a power tool and the bus bar is within the power tool.

In some aspects, the third section is fixed to the first section and the second section by laser welding.

In some aspects, the third section is fixed to the first section and the second section by interlocking geometry.

In some aspects, the second material is a nickel alloy.

In some aspects, the plurality of voltage taps is fixed to the first section and the second section of the bus bar.

In some aspects, the plurality of voltage taps is fixed to the third section of the bus bar.

In some aspects, the first material is copper.

Battery packs described herein include a conductive path for passing electric current, the battery pack including. The battery packs also include a housing, a battery cell positioned within the housing, a battery pack interface, a bus bar connected in the conductive path and electrically connected to the battery pack interface and the battery cell, and a plurality of voltage taps connected to the bus bar. The battery packs also include a controller electrically connected to the plurality of voltage taps. The controller is configured to monitor a parameter of the battery pack using the plurality of voltage taps, detect a fault condition of the battery pack based on the parameter of the battery pack, and initiate a safety operation based on the fault condition.

In some aspects, the parameter of the battery pack is a voltage drop across the bus bar, and the controller is configured to detect the fault condition by determining a current through the bus bar based on the voltage drop.

In some aspects, the fault condition includes an over current condition.

In some aspects, the fault condition includes at least one selected from a group consisting of: an overvoltage condition of the battery cell; an under voltage condition of the battery cell; and an over temperature condition of the battery pack.

In some aspects, the parameter of the battery pack is at least one from a group consisting of: a voltage; a current; or a temperature.

In some aspects, the controller is configured to initiate the safety operation when the fault condition occurs during charging or discharging of the battery pack.

In some aspects, the safety operation includes restricting operation of the battery pack.

In some aspects, the safety operation includes disabling operation of the battery pack.

Bus bars described herein include a first section made of a first material, a second section made of the first material, and a third section made of a second material. The third section is at least partially positioned between the first section and the second section. The second material has a lower temperature coefficient of resistance than the first material. The bus bar also includes a plurality of voltage taps connected to the bus bar.

In some aspects, the first section and the second section are joined to a bottom of the third section and are spaced a distance apart from one another, and wherein the plurality of voltage taps is electrically connected to the first section and the second section.

Before any embodiments are explained in detail, it is to be understood that the embodiments are not limited in application to the details of the configurations and arrangements of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

Unless the context of their usage unambiguously indicates otherwise, the articles “a,” “an,” and “the” should not be interpreted as meaning “one” or “only one.” Rather these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

Relative terminology, such as, for example, “about,” “approximately,” “substantially,” etc., used in connection with a quantity or condition would be understood by those of ordinary skill to be inclusive of the stated value and has the meaning dictated by the context (e.g., the term includes at least the degree of error associated with the measurement accuracy, tolerances [e.g., manufacturing, assembly, use, etc.] associated with the particular value, etc.). Such terminology should also be considered as disclosing the range defined by the absolute values of the two endpoints. For example, the expression “from about 2 to about 4” also discloses the range “from 2 to 4”. The relative terminology may refer to plus or minus a percentage (e.g., 1%, 5%, 10%) of an indicated value.

It should be understood that although certain drawings illustrate hardware and software located within particular devices, these depictions are for illustrative purposes only. Functionality described herein as being performed by one component may be performed by multiple components in a distributed manner. Likewise, functionality performed by multiple components may be consolidated and performed by a single component. In some embodiments, the illustrated components may be combined or divided into separate software, firmware and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable communication links. Similarly, a component described as performing particular functionality may also perform additional functionality not described herein. For example, a device or structure that is “configured” in a certain way is configured in at least that way but may also be configured in ways that are not explicitly listed.

Accordingly, in the claims, if an apparatus, method, or system is claimed, for example, as including a controller, control unit, electronic processor, computing device, logic element, module, memory module, communication channel or network, or other element configured in a certain manner, for example, to perform multiple functions, the claim or claim element should be interpreted as meaning one or more of such elements where any one of the one or more elements is configured as claimed, for example, to make any one or more of the recited multiple functions, such that the one or more elements, as a set, perform the multiple functions collectively.

Other aspects of the embodiments will become apparent by consideration of the detailed description and accompanying drawings.

### BRIEF DESCRIPTION OF THE DRAWINGS

FIG. 1 illustrates a battery pack that includes a bus bar, according to embodiments described herein.

FIG. 2 illustrates a control system for the battery pack of FIG. 1, according to embodiments described herein.

FIG. 3 illustrates a power tool device that includes a bus bar, according to embodiments described herein.

FIG. 4 illustrates a control system for the power tool device of FIG. 3, according to embodiments described herein.

FIG. 5 illustrates a battery pack charger that includes a bus bar, according to embodiments described herein.

FIG. 6 illustrates a control system for the battery pack charger of FIG. 5, according to embodiments described herein.

FIG. 7 illustrates a bus bar, according to embodiments described herein.

FIG. 8 illustrates a bus bar, according to embodiments described herein.

FIG. 9 illustrates a bus bar, according to embodiments described herein.

FIG. 10 illustrates an interface between two portions of a bus bar, according to embodiments described herein.

FIG. 11 illustrates a bus bar, according to embodiments described herein.

FIG. 12 illustrates an interface between two portions of a bus bar, according to embodiments described herein.

### DETAILED DESCRIPTION

Embodiments described herein relate to one or more devices (e.g., high-power devices) that include a path for passing electric current. The devices include a bus bar connected in the path for measuring electric current on the path. For example, the one or more devices include a battery pack, a power tool, and/or a battery pack charger. The bus bar includes a first section made from a first material, a second section made from the first material, a third section made of a second material, and a plurality of voltage taps electrically connected to the bus bar. The second material has a lower temperature coefficient of resistance than the first material. The plurality of voltage taps is used to measure a voltage drop across the third section.

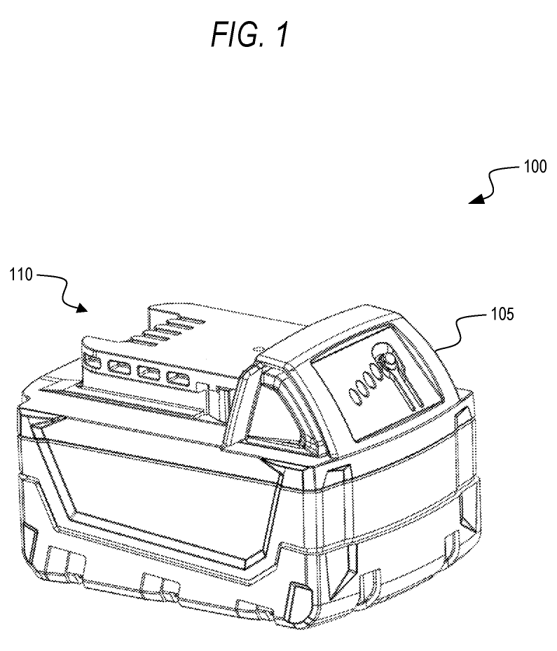

FIG. 1 illustrates a battery pack 100 that includes a bus bar. The battery pack 100 includes a housing 105 and an interface portion 110 for connecting the battery pack 100 to a device (e.g., a power tool). The bus bar is configured, for example, for measuring a current coming into the battery pack 100 (e.g., charging current) or out of the battery pack 100 (e.g., discharge current) by measuring a voltage across a portion of the bus bar. In some embodiments, the bus bar is provided in a charge path or in a discharge path or in a path that both charges and discharges. In some embodiments, the bus bar is a discrete component that includes one or more inputs and one or more outputs for passing current. In some embodiments, the bus bar does not include a casing or a housing and the bus bar is generally exposed. In some embodiments, the bus bar is connected to a printed circuit board (“PCB”) as a singular unit. In other embodiments, a plurality of discrete components is individually connected to a PCB and connected such that the plurality of discrete components collectively forms a bus bar. In some embodiments, the battery pack 100 includes a plurality of bus bars.

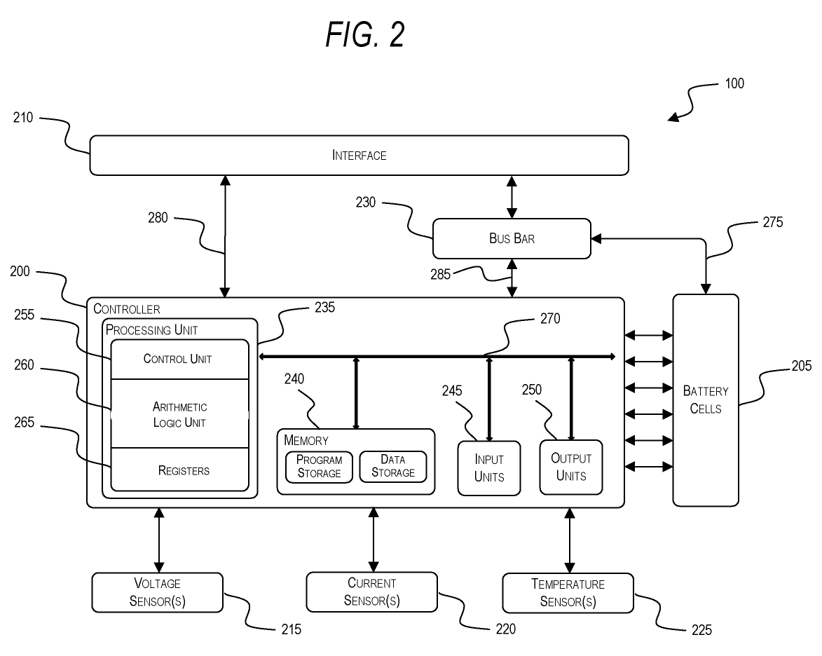

FIG. 2 illustrates a control system for the battery pack 100. The control system includes a controller 200. The controller 200 is electrically and/or communicatively connected to a variety of modules or components of the battery pack 100. For example, the illustrated controller 200 is connected to one or more battery cells 205 and an interface 210 (e.g., the interface portion 110 of the battery pack 100 illustrated in FIG. 1). The controller 200 is also connected to one or more voltage sensors or voltage sensing circuits 215, one or more current sensors or current sensing circuits 220, and one or more temperature sensors or temperature sensing circuits 225. A bus bar 230 is connected between the one or more battery cells 205 and the interface 210. As described in greater detail below, the bus bar 230 can include multiple portions made of different materials. For example, a first portion of the bus bar 230 is made from a first material, and a second portion of the bus bar 230 is made from a second material. The second material has a lower temperature coefficient of resistance than the first material. A voltage across the second portion can be measured or detected and used to determine a current that is passing through the bus bar 230. The controller 200 includes combinations of hardware and software that are operable to, among other things, control the operation of the battery pack 100, monitor a condition of the battery pack 100, enable or disable charging of the battery pack 100, enable or disable discharging of the battery pack 100, etc.

The controller 200 includes a plurality of electrical and electronic components that provide power, operational control, and protection to the components and modules within the controller 200 and/or the battery pack 100. For example, the controller 200 includes, among other things, a processing unit 235 (e.g., a microprocessor, a microcontroller, an electronic controller, and electronic processor, or another suitable programmable device), a memory 240, input units 245, and output units 250. The processing unit 235 includes, among other things, a control unit 255, an arithmetic logic unit (“ALU”) 260, and a plurality of registers 265 (shown as a group of registers in FIG. 2) and is implemented using a known computer architecture (e.g., a modified Harvard architecture, a von Neumann architecture, etc.). The processing unit 235, the memory 240, the input units 245, and the output units 250, as well as the various modules or circuits connected to the controller 200 are connected by one or more control and/or data buses (e.g., common bus 270). The control and/or data buses are shown generally in FIG. 2 for illustrative purposes. The use of one or more control and/or data buses for the interconnection between and communication among the various modules, circuits, and components would be known to a person skilled in the art in view of the invention described herein.

The memory 240 is a non-transitory computer readable medium and includes, for example, a program storage area and a data storage area. The program storage area and the data storage area can include combinations of different types of memory, such as a ROM, a RAM (e.g., DRAM, SDRAM, etc.), EEPROM, flash memory, a hard disk, an SD card, or other suitable magnetic, optical, physical, or electronic memory devices. The processing unit 235 is connected to the memory 240 and executes software instructions that are capable of being stored in a RAM of the memory 240 (e.g., during execution), a ROM of the memory 240 (e.g., on a generally permanent basis), or another non-transitory computer readable medium such as another memory or a disc. Software included in the implementation of the battery pack 100 can be stored in the memory 240 of the controller 200. The software includes, for example, firmware, one or more applications, program data, filters, rules, one or more program modules, and other executable instructions. The controller 200 is configured to retrieve from the memory 240 and execute, among other things, instructions related to the control processes and methods described herein. In other constructions, the controller 200 includes additional, fewer, or different components.

The interface 210 includes a combination of mechanical components (e.g., rails, grooves, latches, etc.) and electrical components (e.g., one or more terminals) configured to and operable for interfacing (e.g., mechanically, electrically, and communicatively connecting) the battery pack 100 with another device (e.g., a power tool, a battery pack charger, etc.). For example, the interface 210 is configured to receive power through the bus bar 230 via a power line 275 between the one or more battery cells 205 and the interface 210. The interface 210 is also configured to communicatively connect to the controller 200 via a communications line 280. In some embodiments, the controller 200 is also electrically connected to the bus bar 230 via a signal line 285.

The controller 200 is configured to determine whether a fault condition of the battery pack 100 is present and generate one or more control signals related to the fault condition. For example, the controller 200 is configured to detect an overvoltage condition of the one or more battery cells 205, and under voltage condition of the one or more battery cells 205, an over current condition (e.g., during charging or discharging), or an over temperature condition (e.g., during charging or discharging). In some embodiments, the over current condition corresponds to a particular current that is sensed for a particular amount of time. In some embodiments, an over current condition is detected when a current of between approximately 30 Amperes and 60 Amperes is detected for a predetermined amount of time (e.g., between 100 nano-seconds and 50 milli-seconds, or between 100 milli-seconds and 2 seconds). The amount of time and the detected current can be varied for different applications. In some embodiments, a current of between 30 Amperes and 60A Amperes can be detected for up to 50 milli-seconds before a fault condition occurs. In other embodiments, a current of between 30 Amperes and 60A Amperes can be detected for between 50 milli-seconds and several minutes (e.g., between 1 minute and 20 minutes) before a fault condition occurs. In some embodiments, a current of greater than 60 Amperes can be detected for between 50 milli-seconds and several minutes (e.g., between 1 minute and 20 minutes) before a fault condition occurs. In some embodiments, a current of approximately 60 Amperes can be detected for approximately 50 milli-seconds before a fault condition occurs. In some embodiments, a current of approximately 70 Amperes can be detected for approximately 100 nano-seconds before a fault condition occurs. In some embodiments, the current depends on the path in which the bus bar is placed. For example, in a charging path, a current of approximately 5 Amperes to 20 Amperes can be detected for approximately 100 milli-seconds up to 2 seconds before a fault occurs. In a discharging path, a current of approximately 20 Amperes to 150 Amperes can be detected for approximately 500 milli-seconds up to 2 seconds before a fault occurs.

In some embodiments, the current threshold, the time threshold, or both the current threshold are adjusted based upon which device is connected to the device with the bus bar. For example, if the bus bar is in a charger, the charger could have a different current threshold depending on the charging capability of the battery pack connected to it.

If the controller 200 detects one or more fault conditions of the battery pack 100 or determines that a fault condition of the battery pack no longer exists, the controller 200 is configured to provide information and/or control signals to another component of the battery pack 100 (e.g. the interface 210, the bus bar 230, etc.). The signals can be configured to, for example, shut down the device, etc. In some embodiments, the controller 200 is configured to independently sense or monitor a parameter of the battery pack 100 and independently restrict operation of the battery pack 100 based on the sensed or monitored parameter through the bus bar 230. For example, the controller 200 is configured to monitor a parameter (e.g., a voltage, a current, a temperature, etc.) across the bus bar 230.

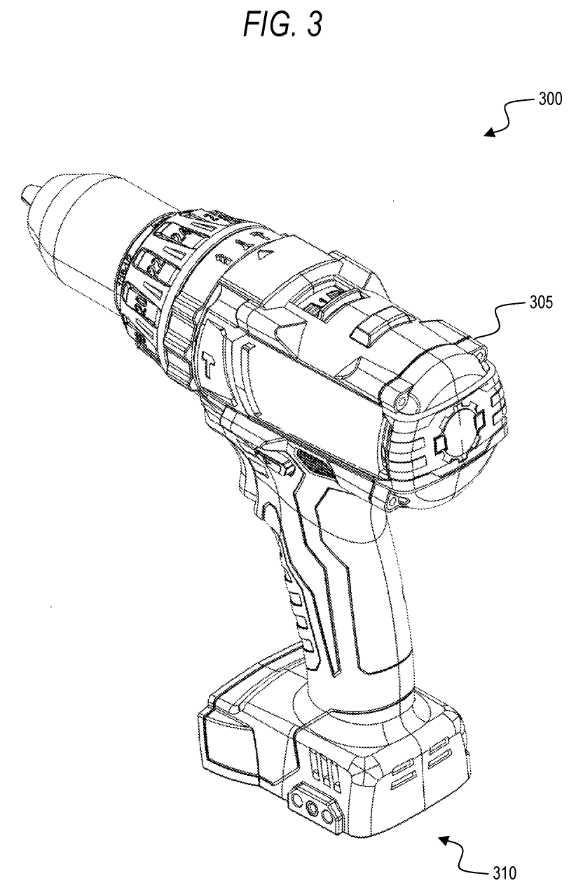

FIG. 3 illustrates a device 300 that includes a bus bar. In the embodiment illustrated in FIG. 3, the device 300 is a power tool (e.g., a drill/driver). In other embodiments, the device 300 is a different type of power tool (e.g., an impact wrench, a ratchet, a saw, a hammer drill, an impact driver, a rotary hammer, a grinder, a blower, a trimmer, etc.) or a different type of device (e.g., a light, a non-motorized sensing tool, etc.). The device 300 includes a housing 305 and an interface portion 310 for connecting the device 300 to, for example, the battery pack 100 or another device. The bus bar is configured, for example, for measuring a current coming into the device 300 by measuring a voltage across a portion of the bus bar. In some embodiments, the bus bar is provided in a discharge path. In some embodiments, the bus bar is a discrete component that includes one or more inputs and one or more outputs for passing current. In some embodiments, the bus bar does not include a casing or a housing and the bus bar is generally exposed. In some embodiments, the bus bar is connected to a printed circuit board (“PCB”) as a singular unit. In other embodiments, a plurality of discrete components is individually connected to a PCB and connected such that the plurality of discrete components collectively forms a bus bar. In some embodiments, the device 300 includes a plurality of bus bars.

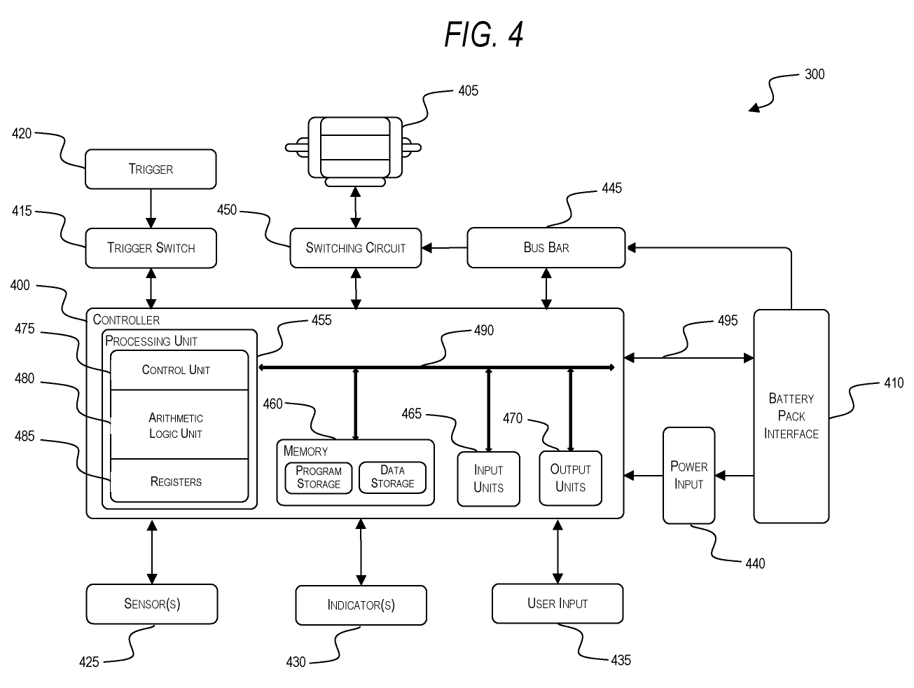

FIG. 4 illustrates a control system for the device 300. The control system includes a controller 400. The controller 400 is electrically and/or communicatively connected to a variety of modules or components of the device 300. For example, the illustrated controller 400 is electrically connected to a motor 405, a battery pack interface 410, a trigger switch 415 (connected to a trigger 420), one or more sensors or sensing circuits 425, one or more indicators 430, a user input module 435, a power input module 440, a bus bar 445, and a switching circuit or module 450 (e.g., including a single stitching FET for a brushed motor or a plurality of switching FETs for a brushless motor). The controller 400 includes combinations of hardware and software that are operable to, among other things, control the operation of the device 300, monitor the operation of the device 300, activate the one or more indicators 430 (e.g., an LED), etc. The bus bar 445 is connected between the battery pack interface 410 and the switching module 450. As described in greater detail below, the bus bar 445 can include multiple portions made of different materials. For example, a first portion of the bus bar 445 is made from a first material, and a second portion of the bus bar 445 is made from a second material. The second material has a lower temperature coefficient of resistance than the first material. A voltage across the second portion can be measured or detected and used to determine a current that is passing through the bus bar 445. The controller 400 includes combinations of hardware and software that are operable to, among other things, control the operation of the device 300, monitor a condition of the device 300, etc.

The controller 400 includes a plurality of electrical and electronic components that provide power, operational control, and protection to the components and modules within the controller 400 and/or the device 300. For example, the controller 400 includes, among other things, a processing unit 455 (e.g., a microprocessor, a microcontroller, an electronic controller, an electronic processor, or another suitable programmable device), a memory 460, input units 465, and output units 470. The processing unit 455 includes, among other things, a control unit 475, an ALU 480, and a plurality of registers 485 (shown as a group of registers in FIG. 4) and is implemented using a known computer architecture (e.g., a modified Harvard architecture, a von Neumann architecture, etc.). The processing unit 455, the memory 460, the input units 465, and the output units 470, as well as the various modules or circuits connected to the controller 400 are connected by one or more control and/or data buses (e.g., common bus 490). The control and/or data buses are shown generally in FIG. 4 for illustrative purposes. The use of one or more control and/or data buses for the interconnection between and communication among the various modules, circuits, and components would be known to a person skilled in the art in view of the invention described herein.

The memory 460 is a non-transitory computer readable medium and includes, for example, a program storage area and a data storage area. The program storage area and the data storage area can include combinations of different types of memory, such as a ROM, a RAM (e.g., DRAM, SDRAM, etc.), EEPROM, flash memory, a hard disk, an SD card, or other suitable magnetic, optical, physical, or electronic memory devices. The processing unit 455 is connected to the memory 460 and executes software instructions that are capable of being stored in a RAM of the memory 460 (e.g., during execution), a ROM of the memory 460 (e.g., on a generally permanent basis), or another non-transitory computer readable medium such as another memory or a disc. Software included in the implementation of the device 300 can be stored in the memory 460 of the controller 400. The software includes, for example, firmware, one or more applications, program data, filters, rules, one or more program modules, and other executable instructions. The controller 400 is configured to retrieve from the memory 460 and execute, among other things, instructions related to the control processes and methods described herein. In other constructions, the controller 400 includes additional, fewer, or different components.

The battery pack interface 410 includes a combination of mechanical components (e.g., rails, grooves, latches, etc.) and electrical components (e.g., one or more terminals) configured to and operable for interfacing (e.g., mechanically, electrically, and communicatively connecting) the device 300 with a battery pack (e.g., the battery pack 100). For example, power provided by the battery pack 100 to the device 300 is provided through the battery pack interface 410 to the power input module 440. The power input module 440 includes combinations of active and passive components to regulate or control the power received from the battery pack 100 prior to power being provided to the controller 400. The battery pack interface 410 also supplies power to the switching module 450 through the bus bar 445 to be switched by the switching to selectively provide power to the motor 405. The battery pack interface 410 also includes, for example, a communication line 495 for provided a communication line or link between the controller 400 and the battery pack 100. In some embodiments, the controller 400 is also electrically and/or communicatively connected to the bus bar 445 via a signal line.

The indicators 430 include, for example, one or more light-emitting diodes (“LEDs”). The indicators 430 can be configured to display conditions of, or information associated with, the device 300. For example, the indicators 430 are configured to indicate measured electrical characteristics of the device 300, the status of the device, etc. The user input module 435 is operably coupled to the controller 400 to, for example, select a forward mode of operation or a reverse mode of operation, a torque and/or speed setting for the device 300 (e.g., using torque and/or speed switches), etc. In some embodiments, the user input module 435 includes a combination of digital and analog input or output devices required to achieve a desired level of operation for the device 300, such as one or more knobs, one or more dials, one or more switches, one or more buttons, etc.

The controller 400 is configured to determine whether a fault condition of the device 300 is present and generate one or more control signals related to the fault condition. For example, the sensing circuits 425 include one or more current sensors (e.g., bus bar 445), one or more speed sensors, one or more Hall Effect sensors, one or more temperature sensors, etc. The controller 400 calculates or includes, within memory 460, predetermined operational threshold values and limits for operation of the device 300. For example, when a potential thermal failure (e.g., of a FET, the motor 405, etc.) is detected or predicted by the controller 400, power to the motor 405 can be limited or interrupted until the potential for thermal failure is reduced. If the controller 400 detects one or more such fault conditions of the device 300 or determines that a fault condition of the device 300 no longer exists, the controller 400 is configured to provide information and/or control signals to another component of the battery pack 100 (e.g. the battery pack interface 410, the indicators 430, etc.). In some embodiments, the controller 400 is configured to independently sense or monitor a parameter of the device 300 and independently restrict operation of the battery pack 100 based on the sensed or monitored parameter through bus bar 445.

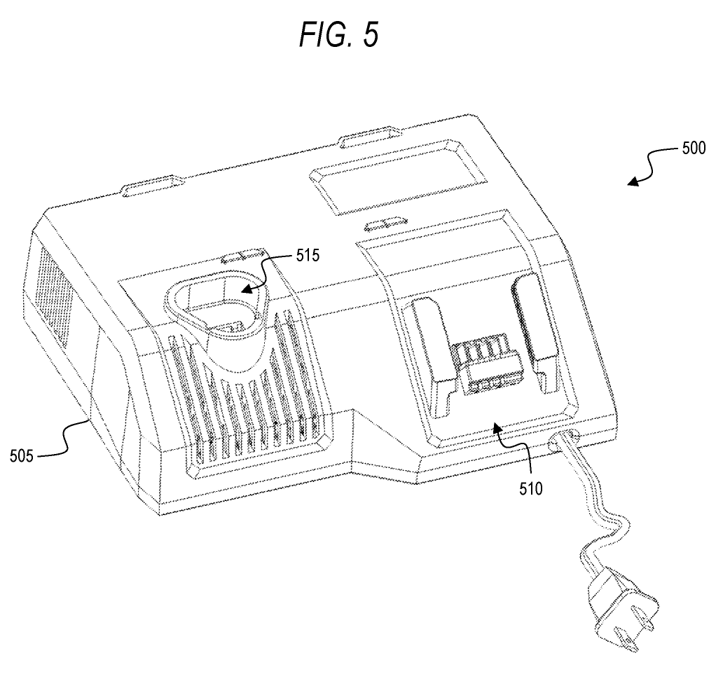

FIG. 5 illustrates a battery pack charger 500 that includes a bus bar. The battery pack charger 500 includes a housing 505 and interface portions 510, 515 for connecting the battery pack charger 500 to one or more battery packs (e.g., battery pack 100). The bus bar is configured, for example, for measuring a current out of the battery pack charger 500 by measuring a voltage across a portion of the bus bar. In some embodiments, the bus bar is provided in a charge path. In some embodiments, the bus bar is a discrete component that includes one or more inputs and one or more outputs for passing current. In some embodiments, the bus bar does not include a casing or a housing and the bus bar is generally exposed. In some embodiments, the bus bar is connected to a printed circuit board (“PCB”) as a singular unit. In other embodiments, a plurality of discrete components is individually connected to a PCB and connected such that the plurality of discrete components collectively forms a bus bar. In some embodiments, the battery pack charger 500 includes a plurality of bus bars.

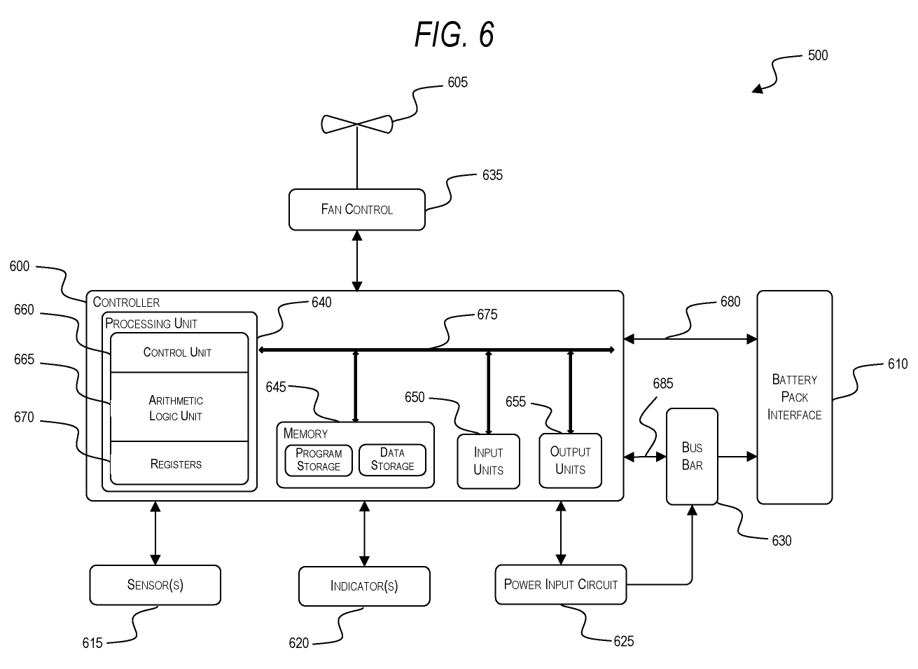

FIG. 6 illustrates a control system for the battery pack charger 500. The control system includes a controller 600. The controller 600 is electrically and/or communicatively connected to a variety of modules or components of the battery pack charger 500. For example, the illustrated controller 600 is electrically connected to a fan 605, a battery pack interface 610 (e.g., interface portions 510, 515), one or more sensors or sensing circuits 615 (e.g., current sensors, temperature sensors, etc.), one or more indicators 620, a power input circuit 625, a bus bar 630, and a fan control module or circuit 635. The controller 600 includes combinations of hardware and software that are operable to, among other things, control the operation of the battery pack charger 500, determine a temperature of a heatsink, activate the indicators 620 (e.g., one or more LEDs), etc.

The controller 600 includes a plurality of electrical and electronic components that provide power, operational control, and protection to the components and modules within the controller 600 and/or battery pack charger 500. For example, the controller 600 includes, among other things, a processing unit 640 (e.g., a microprocessor, a microcontroller, an electronic controller, an electronic processor, or another suitable programmable device), a memory 645, input units 650, and output units 655. The processing unit 640 includes, among other things, a control unit 660, an ALU 665, and a plurality of registers 670 (shown as a group of registers in FIG. 6) and is implemented using a known computer architecture (e.g., a modified Harvard architecture, a von Neumann architecture, etc.). The processing unit 640, the memory 645, the input units 650, and the output units 655, as well as the various modules or circuits connected to the controller 600 are connected by one or more control and/or data buses (e.g., common bus 675). The control and/or data buses are shown generally in FIG. 6 for illustrative purposes. The use of one or more control and/or data buses for the interconnection between and communication among the various modules, circuits, and components would be known to a person skilled in the art in view of the invention described herein.

The memory 645 is a non-transitory computer readable medium and includes, for example, a program storage area and a data storage area. The program storage area and the data storage area can include combinations of different types of memory, such as a ROM, a RAM (e.g., DRAM, SDRAM, etc.), EEPROM, flash memory, a hard disk, an SD card, or other suitable magnetic, optical, physical, or electronic memory devices. The processing unit 640 is connected to the memory 645 and executes software instructions that are capable of being stored in a RAM of the memory 645 (e.g., during execution), a ROM of the memory 645 (e.g., on a generally permanent basis), or another non-transitory computer readable medium such as another memory or a disc. Software included in the implementation of the battery pack charger 500 can be stored in the memory 645 of the controller 600. The software includes, for example, firmware, one or more applications, program data, filters, rules, one or more program modules, and other executable instructions. The controller 600 is configured to retrieve from the memory 645 and execute, among other things, instructions related to the control processes and methods described herein. In other constructions, the controller 600 includes additional, fewer, or different components.

The battery pack interface 610 includes a combination of mechanical components (e.g., rails, grooves, latches, etc.) and electrical components (e.g., one or more terminals) configured to and operable for interfacing (e.g., mechanically, electrically, and communicatively connecting) the battery pack charger 500 with a battery pack (e.g., battery pack 100). For example, the battery pack interface 610 is configured to receive power through the bus bar 630 via a power line between the power input circuit 625 and the battery pack interface 610. The battery pack interface 610 is also configured to communicatively connect to the controller 600 via a communications line 680. In some embodiments, the controller 600 is also electrically connected to the bus bar 630 via a signal line 685. As described in greater detail below, the bus bar 630 can include multiple portions made of different materials. For example, a first portion of the bus bar 630 is made from a first material, and a second portion of the bus bar 630 is made from a second material. The second material has a lower temperature coefficient of resistance than the first material. A voltage across the second portion can be measured or detected and used to determine a current that is passing through the bus bar 630. The controller 600 includes combinations of hardware and software that are operable to, among other things, control the operation of the battery pack charger 500, monitor a condition of the battery pack charger, etc.

The controller 600 is configured to determine whether a fault condition of the battery pack charger 500 is present and generate one or more control signals related to the fault condition. For example, the sensors 615 include one or more current sensors, one or more temperature sensors, etc. The controller 600 is configured to detect an over current condition (e.g., when charging the battery pack 100), an over temperature condition, etc. If the controller 600 detects one or more fault conditions of the battery pack charger 500 or determines that a fault condition of the battery pack charger no longer exists, the controller 600 is configured to provide information and/or control signals to another component of the battery pack charger 500 (e.g. the battery pack interface 610, etc.). In some embodiments, the controller 600 is configured to independently sense or monitor a parameter of the battery pack charger 500 and independently restrict operation of the battery pack charger 500 based on the sensed or monitored parameter. For example, the controller 600 is configured to monitor a parameter (e.g., current, etc.) and restrict operation of the battery pack charger 500 based on the current through the bus bar 630.

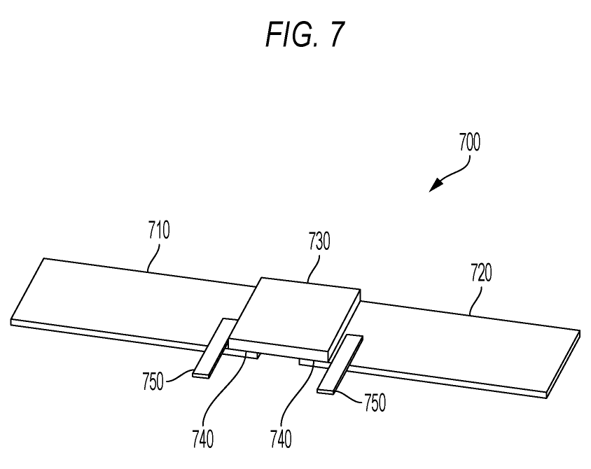

FIG. 7 illustrates a bus bar 700. The bus bar 700 can be implemented in, among other devices, the battery pack 100, the device 300, or the battery pack charger 500. The bus bar 700 includes a first section 710, a second section 720, and a third section 730. The third section 730 is at least partially positioned between the first section 710 and the second section 720. The first section 710 and the second section 720 are made of a first material (e.g., copper). The third section 730 is made of a second material different than the first material. Interfaces 740 are the interfaces at which the first material and the second material are joined. For the illustrated bus bar 700, the first section 710 and the second section 720 are joined to the bottom of the third section 730 and spaced a distance apart from one another. In some embodiments, the third section 730 is fixed to the first section 710 and the second section 720 by laser welding.

Bus bar 700 also includes a plurality of voltage taps 750. The plurality of voltage taps 750 are electrically connected to the bus bar 700. In this embodiment, the plurality of voltage taps 950 is electrically connected to the first section 710 and the second section 720. The plurality of the voltage taps 750 is configured to measure the voltage drop across the third section 730. In some embodiments, the plurality of voltage taps 750 is connected to a controller (e.g., controller 200, 400, 600) configured to, among other things, convert the voltage drop across the third section 730 to a current traveling through the third section 730, where the current traveling through the third section 730 is proportional to the voltage drop across the third section 730. The voltage drop across the third section 730 is a useful measurement in determining an overcurrent and/or an overheating condition. If the controller 200, 400, 600 detects such a condition, the controller 200, 400, 600 is configured to initiate a safety operation in some embodiments. The safety operation initiated by the controller 200, 400, 600 includes, but is not limited to, restricting or disabling operation of, for example, the battery pack 100, the device 300, the battery pack charger 500, etc.

In some embodiments, it is advantageous to implement bus bar 700 because it is advantageous to weld the plurality of voltage taps 750 to the first section 710 and the second section 720 rather than the third section 730 because the first section 710 and the second section 720 are composed of the first material (e.g., copper).

The second material is selected to achieve particular properties for the bus bar 700. For example, the second material should have a low temperature coefficient of resistance, a high thermal conductivity, and a high electrical conductivity. In some embodiments, the second material should be capable of being laser welded to the first material (e.g., copper). In some embodiments, the second material is a nickel alloy. In some embodiments, the second material is a copper-nickel alloy. In some embodiments, the second material includes one or more of nickel, manganese, iron, tin, and zinc. In some embodiments, the second material is a copper-manganese-nickel alloy. For example, the second material can include up to 5% nickel, up to 10% manganese, and up to 3% tin. In some embodiments, the remaining material is a metal such as copper. It may be desirable for the second material to have particular electrical and/or thermal properties. For example, it may be desirable for the second material to have a density (at 20°C) of 8-9 g/cm³ (e.g., approximately 8.5), a thermal conductivity (at 20°C) of 20-40 W/M°K (e.g., 22, 34, etc.), a coefficient of thermal expansion between 20°C and 100°C of 15-20 x10⁻⁶/°C (e.g., 18), an electrical resistivity (at 20°C) of 25-40 μΩcm (e.g., 28, 29, 37, etc.), and a temperature coefficient of electrical resistance between 20°C and 105°C of 0±40 ppm/°C (e.g., 20). In some embodiments, the third section 830 has a resistance of 50 micro-Ohms (“μΩ”) or less (e.g., 25-50 μΩ).

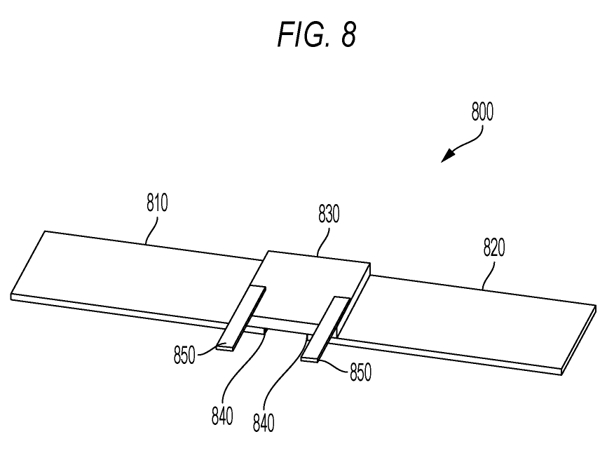

FIG. 8 illustrates a bus bar 800. The bus bar 800 can be implemented in, among other devices, the battery pack 100, the device 300, or the battery pack charger 500. The bus bar 800 includes a first section 810, a second section 820, and a third section 830. The third section 830 is at least partially positioned between the first section 810 and the second section 820. The first section 810 and the second section 820 are made of a first material (e.g., copper). The third section 830 is made of a second material that is different from the first material. Interfaces 840 are the interfaces at which the first material and the second material are joined. For the illustrated bus bar 800, the first section 810 and the second section 820 are joined to the bottom of the third section 830 and are spaced a distanced apart from one another. In some embodiments, the third section 730 is fixed to the first section 710 and the second section 720 by laser welding.

Bus bar 800 also includes a plurality of voltage taps 850. The plurality of voltage taps 850 are electrically connected to the bus bar 800. In this embodiment, the plurality of voltage taps 850 is electrically connected to the third section 830. In some embodiments, it is advantageous to implement bus bar 800 in place of, for example, bus bar 700 in order to obtain more precise voltage drop readings across the third section 830. The plurality of the voltage taps 850 is configured to measure the voltage drop across the third section 830. In some embodiments, the plurality of voltage taps 850 is connected to a controller (e.g., controller 200, 400, 600) that is configured to, among other things, convert the voltage drop across the third section 830 to a current traveling through the third section 830, where the current traveling through the third second 830 is proportional to the voltage drop across the third section 830. The voltage drop across the third section 830 is a useful measurement in determining an overcurrent and/or an overheating condition. If the controller 200, 400, 600 detects such a condition, the controller 200, 400, 600 is configured to initiate a safety operation in some embodiments. The safety operation initiated by the controller 200, 400, 600 includes, but is not limited to, restricting or disabling operation of, for example, the battery pack 100, the device 300, the battery pack charger 500, etc.

The second material is selected to achieve particular properties for the bus bar 800. For example, the second material should have a low temperature coefficient of resistance, a high thermal conductivity, and a high electrical conductivity. In some embodiments, the second material should be capable of being laser welded to the first material (e.g., copper). In some embodiments, the second material is a nickel alloy. In some embodiments, the second material is a copper-nickel alloy. In some embodiments, the second material includes one or more of nickel, manganese, iron, tin, and zinc. In some embodiments, the second material is a copper-manganese-nickel alloy. For example, the second material can include up to 5% nickel, up to 10% manganese, and up to 3% tin. In some embodiments, the remaining material is a metal such as copper. It may be desirable for the second material to have particular electrical and/or thermal properties. For example, it may be desirable for the second material to have a density (at 20°C) of 8-9 g/cm³ (e.g., approximately 8.5), a thermal conductivity (at 20°C) of 20-40 W/M°K (e.g., 22, 34, etc.), a coefficient of thermal expansion between 20°C and 100°C of 15-20 x10⁻⁶/°C (e.g., 18), an electrical resistivity (at 20°C) of 25-40 μΩcm (e.g., 28, 29, 37, etc.), and a temperature coefficient of electrical resistance between 20°C and 105°C of 0±40 ppm/°C (e.g., 20). In some embodiments, the third section 830 has a resistance of 50 micro-Ohms (“μΩ”) or less (e.g., 25-50 μΩ).

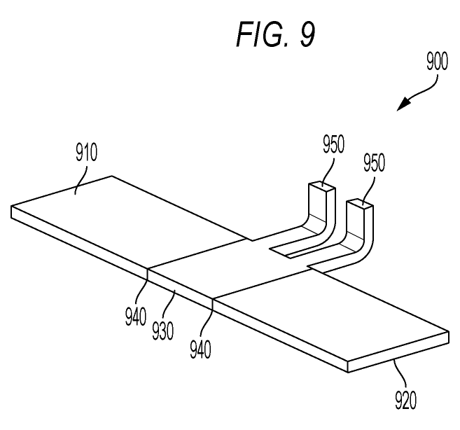

FIG. 9 illustrates a bus bar 900. The bus bar 800 can be implemented in, among other devices, the battery pack 100, the device 300, or the battery pack charger 500. The bus bar 900 includes a first section 910, a second section 920, and a third section 930. The third section 930 is at least partially positioned between the first section 910 and the second section 920. The first section 910 and the second section 920 are made of a first material (e.g., copper). The third section 930 is made of a second material. Interfaces 940 are the interfaces at which the first material and the second material are joined. For the illustrated bus bar 900, the first section 910, the second section 920, and the third section 930 are aligned within the same plane. Additionally, the first section 910 and the third section 930 are joined at the interface 940 face only (e.g., edge lay). The second section 920 and the third section 930 are joined in the same manner. In some embodiments, the first section 910 and the second section 920 are joined to the third section 930 using laser welding.

Bus bar 900 includes a plurality of voltage taps 950. The plurality of voltage taps 950 are electrically connected to the bus bar 900. In this embodiment, the plurality of voltage taps 950 is connected to or formed as a part of the third section 930. In some embodiments, the plurality of voltage taps 950 is composed of the same material as the third section 930. In some embodiments, the plurality of voltage taps 950 are laser welded to the third section 930. In other embodiments, the plurality of voltage taps 950 and the third section 930 form a single integrated section. The plurality of the voltage taps 950 is configured to measure the voltage drop across the third section 930. In some embodiments, the plurality of voltage taps 950 is connected to a controller (e.g., controller 200, 400, 600) that is configured to, among other things, convert the voltage drop across the third section 930 to a current traveling through the third section 930, where the current traveling through the third second 930 is proportional to the voltage drop across the third section 930. The voltage drop across the third section 930 is a useful measurement in determining an overcurrent and/or an overheating condition. If the controller 200, 400, 600 detects such a condition, the controller 200, 400, 600 is configured to initiate a safety operation in some embodiments. The safety operation initiated by the controller 200, 400, 600 includes, but is not limited to, restricting or disabling operation of, for example, the battery pack 100, the device 300, the battery pack charger 500, etc.

The second material is selected to achieve particular properties for the bus bar 900. For example, the second material should have a low temperature coefficient of resistance, a high thermal conductivity, and a high electrical conductivity. In some embodiments, the second material should be capable of being laser welded to the first material (e.g., copper). In some embodiments, the second material is a nickel alloy. In some embodiments, the second material is a copper-nickel alloy. In some embodiments, the second material includes one or more of nickel, manganese, iron, tin, and zinc. In some embodiments, the second material is a copper-manganese-nickel alloy. For example, the second material can include up to 5% nickel, up to 10% manganese, and up to 3% tin. In some embodiments, the remaining material is a metal such as copper. It may be desirable for the second material to have particular electrical and/or thermal properties. For example, it may be desirable for the second material to have a density (at 20°C) of 8-9 g/cm³ (e.g., approximately 8.5), a thermal conductivity (at 20°C) of 20-40 W/M°K (e.g., 22, 34, etc.), a coefficient of thermal expansion between 20°C and 100°C of 15-20 x10⁻⁶/°C (e.g., 18), an electrical resistivity (at 20°C) of 25-40 μΩcm (e.g., 28, 29, 37, etc.), and a temperature coefficient of electrical resistance between 20°C and 105°C of 0±40 ppm/°C (e.g., 20). In some embodiments, the third section 830 has a resistance of 50 micro-Ohms (“μΩ”) or less (e.g., 25-50 μΩ).

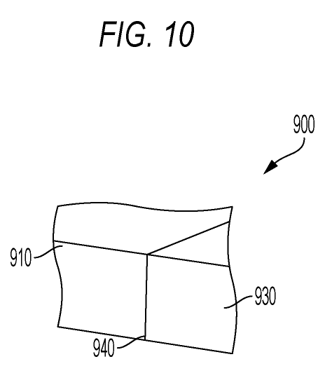

FIG. 10 illustrates the interface 940 between two materials of the bus bar 900. The interface 940 between the two materials includes the first section 910 and the third section 930. The first section 910 is a first material and the third section 930 is a second material, wherein the first material is different from the second material. As previously described with respect to FIG. 9, interface 940 is the interface at which the first material and the second material are joined.

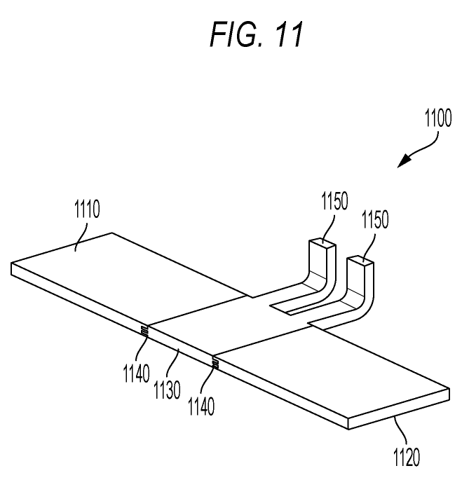

FIG. 11 illustrates a bus bar 1100. The bus bar 800 can be implemented in, among other devices, the battery pack 100, the device 300, or the battery pack charger 500. The bus bar 1100 includes a first section 910, a second section 1120, and a third section 1130. The third section 1130 is at least partially positioned between the first section 1110 and the second section 1120. The first section 1110 and the second section 1120 are made of a first material (e.g., copper). The third section 1130 is made of a second material. Interfaces 1140 are the interfaces at which the first material and the second material are joined. For the illustrated bus bar 1100, the first section 1110, the second section 1120, and the third section 1130 are aligned within the same plane. Additionally, the first section 1110 and the third section 1130 are joined at the interface 1140 (e.g., interlocking edge lay). The second section 1120 and the third section 1130 are joined in the same manner. In some embodiments, the first section 1110 and the second section 1120 are joined to the third section 1130 by laser welding.

Bus bar 1100 also includes a plurality of voltage taps 1150. The plurality of voltage taps 1150 are electrically connected to the bus bar 1100. In this embodiment, the plurality of voltage taps 1150 is connected to or formed as a part of the third section 1130. In some embodiments, the plurality of voltage taps 1150 is composed of the same material as the third section 1130. In some embodiments, the plurality of voltage taps 1150 are laser welded to the third section 1130. In other embodiments, the plurality of voltage taps 1150 and the third section 1130 form a single integrated section. The plurality of the voltage taps 1150 is configured to measure the voltage drop across the third section 1130. In some embodiments, the plurality of voltage taps 1150 is connected to a controller (e.g., controller 200, 400, 600) that is configured to, among other things, convert the voltage drop across the third section 1130 to a current traveling through the third section 1130, where the current traveling through the third section 1130 is proportional to the voltage drop across the third section 1130. The voltage drop across the third section 1130 is a useful measurement in determining an overcurrent and/or an overheating condition. If the controller 200, 400, 600 detects such a condition, the controller 200, 400, 600 is configured to initiate a safety operation in some embodiments. The safety operation initiated by the controller 200, 400, 600 includes, but is not limited to, restricting or disabling operation of, for example, the battery pack 100, the device 300, the battery pack charger 500, etc.

The second material is selected to achieve particular properties for the bus bar 1100. For example, the second material should have a low temperature coefficient of resistance, a high thermal conductivity, and a high electrical conductivity. In some embodiments, the second material should be capable of being laser welded to the first material (e.g., copper). In some embodiments, the second material is a nickel alloy. In some embodiments, the second material is a copper-nickel alloy. In some embodiments, the second material includes one or more of nickel, manganese, iron, tin, and zinc. In some embodiments, the second material is a copper-manganese-nickel alloy. For example, the second material can include up to 5% nickel, up to 10% manganese, and up to 3% tin. In some embodiments, the remaining material is a metal such as copper. It may be desirable for the second material to have particular electrical and/or thermal properties. For example, it may be desirable for the second material to have a density (at 20°C) of 8-9 g/cm³ (e.g., approximately 8.5), a thermal conductivity (at 20°C) of 20-40 W/M°K (e.g., 22, 34, etc.), a coefficient of thermal expansion between 20°C and 100°C of 15-20 x10⁻⁶/°C (e.g., 18), an electrical resistivity (at 20°C) of 25-40 μΩcm (e.g., 28, 29, 37, etc.), and a temperature coefficient of electrical resistance between 20°C and 105°C of 0±40 ppm/°C (e.g., 20). In some embodiments, the third section 830 has a resistance of 50 micro-Ohms (“μΩ”) or less (e.g., 25-50 μΩ).

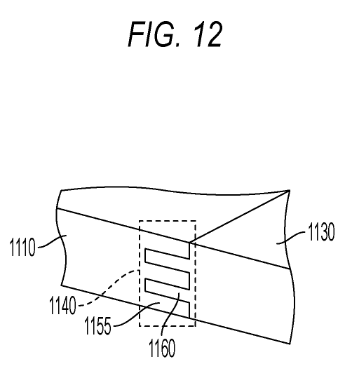

FIG. 12 illustrates the interface 1140 between two materials. The interface 1140 between two materials includes the first section 1110 and the third section 1130. The first section 1110 is a first material, and the third section 1130 is a second material, wherein the first material is different from the second material. As previously described with respect to FIG. 11, interface 1140 is the interface at which the first material and the second material are joined. Additionally, the first section 1110 and the third section 1130 are joined together at interface 1140 with an interlocking geometry (e.g., interlocking edge lay). For example, the first section 1110 includes a plurality of arms 1155 configured to interlock with a plurality of arms 1160 of the third section 1130.

### REPRESENTATIVE FEATURES

Representative features are set out in the following clauses, which stand alone or may be combined, in any combination, with one or more features disclosed in the text and/or drawings of the specification.

Clause 1. A device including a conductive path for passing electric current, the device comprising: a terminal of the device; and a bus bar connected in the conductive path and electrically connected to the terminal of the device, the bus bar including: a first section made of a first material, a second section made of the first material, a third section made of a second material, the third section at least partially positioned between the first section and the second section, the second material having a lower temperature coefficient of resistance than the first material, and a plurality of voltage taps electrically connected to the bus bar, the plurality of voltage taps operable to measure a voltage across the third section.

Clause 2. The device of clause 1, wherein the device is a battery pack and the bus bar is within the battery pack.

Clause 3. The device of clause 1, wherein the device is a battery pack charger and the bus bar is within the battery pack charger.

Clause 4. The device of clause 1, wherein the device is a power tool and the bus bar is within the power tool.

Clause 5. The device of any preceding clause, wherein the third section is fixed to the first section and the second section by laser welding.

Clause 6. The device of any preceding clause, wherein the third section is fixed to the first section and the second section by interlocking geometry.

Clause 7. The device of any preceding clause, wherein the second material is a nickel alloy.

Clause 8. The device of any preceding clause, wherein the plurality of voltage taps is fixed to the first section and the second section of the bus bar.

Clause 9. The device of any preceding clause, wherein the plurality of voltage taps is fixed to the third section of the bus bar.

Clause 10. The device of clause 1, wherein the first material is copper.

Clause 11. A battery pack including a conductive path for passing electric current, the battery pack comprising: a housing; a battery cell positioned within the housing; a battery pack interface; a bus bar connected in the conductive path and electrically connected to the battery pack interface and the battery cell, a plurality of voltage taps connected to the bus bar; and a controller electrically connected to the plurality of voltage taps, the controller configured to: monitor a parameter of the battery pack using the plurality of voltage taps, detect a fault condition of the battery pack based on the parameter of the battery pack, and initiate a safety operation based on the fault condition.

Clause 12. The battery pack of clause 11, wherein the parameter of the battery pack is a voltage drop across the bus bar, and the controller is configured to detect the fault condition by determining a current through the bus bar based on the voltage drop.

Clause 13. The battery pack of clause 12, wherein the fault condition is an over current condition.

Clause 14. The battery pack of any of clauses 11-13, wherein the fault condition includes at least one selected from a group consisting of: an overvoltage condition of the battery cell; an under voltage condition of the battery cell; and an over temperature condition of the battery pack.

Clause 15. The battery pack of any of clauses 11-14, wherein the parameter of the battery pack is at least one selected from a group consisting of: a voltage; a current; and a temperature.

Clause 16. The battery pack of any of clauses 11-15, wherein the controller is configured to initiate the safety operation when the fault condition occurs during charging or discharging of the battery pack.

Clause 17. The battery pack of any of clauses 11-16, wherein the safety operation includes restricting operation of the battery pack.

Clause 18. The battery pack of any of clauses 11-16, wherein the safety operation includes disabling operation of the battery pack.

Clause 19. A bus bar comprising: a first section made of a first material; a second section made of the first material; a third section made of a second material, the third section at least partially positioned between the first section and the second section, the second material having a lower temperature coefficient of resistance than the first material; and a plurality of voltage taps connected to the bus bar.

Clause 20. The bus bar of clause 19, wherein: the first section and the second section are joined to a bottom of the third section and are spaced a distance apart from one another; and the plurality of voltage taps is electrically connected to the first section and the second section.

Thus, embodiments described herein provide, among other things, devices that include a current measurement bus bar. Various features and advantages are set forth in the following claims.

What is claimed is:

1. A device including a conductive path for passing electric current, the device comprising:
a terminal of the device; and
a bus bar connected in the conductive path and electrically connected to the terminal of the device, the bus bar including:
a first section made of a first material,
a second section made of the first material,
a third section made of a second material, the third section at least partially positioned between the first section and the second section, the second material having a lower temperature coefficient of resistance than the first material, and
a plurality of voltage taps electrically connected to the bus bar, the plurality of voltage taps operable to measure a voltage across the third section.

2. The device of claim 1, wherein the device is a battery pack and the bus bar is within the battery pack.

3. The device of claim 1, wherein the device is a battery pack charger and the bus bar is within the battery pack charger.

4. The device of claim 1, wherein the device is a power tool and the bus bar is within the power tool.

5. The device of claim 1, wherein the third section is fixed to the first section and the second section by laser welding.

6. The device of claim 1, wherein the third section is fixed to the first section and the second section by interlocking geometry.

7. The device of claim 1, wherein the second material is a nickel alloy.

8. The device of claim 1, wherein the plurality of voltage taps is fixed to the first section and the second section of the bus bar.

9. The device of claim 1, wherein the plurality of voltage taps is fixed to the third section of the bus bar.

10. The device of claim 1, wherein the first material is copper.

11. A battery pack including a conductive path for passing electric current, the battery pack comprising:
a housing;
a battery cell positioned within the housing;
a battery pack interface;
a bus bar connected in the conductive path and electrically connected to the battery pack interface and the battery cell,
a plurality of voltage taps connected to the bus bar; and
a controller electrically connected to the plurality of voltage taps, the controller configured to:
monitor a parameter of the battery pack using the plurality of voltage taps,
detect a fault condition of the battery pack based on the parameter of the battery pack, and
initiate a safety operation based on the fault condition.

12. The battery pack of claim 11, wherein the parameter of the battery pack is a voltage drop across the bus bar, and the controller is configured to detect the fault condition by determining a current through the bus bar based on the voltage drop.

13. The battery pack of claim 12, wherein the fault condition is an over current condition.

14. The battery pack of claim 11, wherein the fault condition includes at least one selected from a group consisting of: an overvoltage condition of the battery cell; an under voltage condition of the battery cell; and an over temperature condition of the battery pack.

15. The battery pack of claim 11, wherein the parameter of the battery pack is at least one selected from a group consisting of: a voltage; a current; and a temperature.

16. The battery pack of claim 11, wherein the controller is configured to initiate the safety operation when the fault condition occurs during charging or discharging of the battery pack.

17. The battery pack of claim 11, wherein the safety operation includes restricting operation of the battery pack.

18. The battery pack of claim 11, wherein the safety operation includes disabling operation of the battery pack.

19. A bus bar comprising:
a first section made of a first material;
a second section made of the first material;
a third section made of a second material, the third section at least partially positioned between the first section and the second section, the second material having a lower temperature coefficient of resistance than the first material; and
a plurality of voltage taps connected to the bus bar.

20. The bus bar of claim 19, wherein:
the first section and the second section are joined to a bottom of the third section and are spaced a distance apart from one another; and
the plurality of voltage taps is electrically connected to the first section and the second section.
